(19) United States
(12) Patent Application Publication
(10) Pub. No.: US 2008/0185500 A1
(43) Pub. Date: Aug. 7, 2008

(54) SOLID-STATE IMAGING DEVICE AND METHOD THEREOF

(75) Inventor: Kimiaki Toshikiyo, Osaka (JP)

Correspondence Address: GREENBLUM & BERNSTEIN, P.L.C., 1950 ROLAND CLARKE PLACE, RESTON, VA, 20191, US

(73) Assignee: MATSUSHITA ELECTRIC INDUSTRIAL CO., LTD., Osaka (JP)

(21) Appl. No.: 12/023,179

(22) Filed: Jan. 31, 2008

(30) Foreign Application Priority Data
Feb. 2, 2007 (JP) 2007-024738

(51) Int. Cl. H01L 27/00; H01L 21/00

(52) U.S. Cl. 250/208.1; 438/70; 257/E21.001

(57) ABSTRACT

A solid-state imaging device and the like are provided. The solid-state imaging device includes a light-collecting element capable of efficiently collecting incident light by improving reproducibility of refractive index distribution at the borders of pixels. Each of the pixels (a square size of 5.6 μm) includes: a light-collecting element (distributed index lens); a color filter; a light-blocking layer (AI wiring); a light-receiving element (Si photo diode); a Si substrate; and a planarization film. The light-collecting element has a concentric structure which is made up of SiO2 (n=1.43) and has a film thickness of 1.2 μm and 0.8 μm which forms a two-tiered structure. The light-collecting element has a structure in which SiO2 (n=1.43) is curved out to define a concentric pattern and the surrounding medium is air (n=1). Further, an air gap (width: a) is provided between adjacent two light-collecting elements.

### BACKGROUND OF THE INVENTION

(1) Field of the Invention

The present invention relates to a solid-state imaging device and a method of the same used for digital cameras and the like.

(2) Description of the Related Art

Along with the widespread use of digital cameras, camera-equipped cell phones, and the like, the market for solid-state imaging devices has seen a remarkable growth. In a Charge-Coupled Device (CCD) and a Complementary Metal-Oxide Semiconductor (CMOS) image sensor (hereinafter also simply referred to as “image sensor”) which are currently commonly used as solid-state imaging devices, a semiconductor integrated circuit which has plural light-receiving sections is two-dimensionally arranged and converts light signals from an object into electric signals.

The sensitivity of solid-state imaging devices depends on the amount of output current of light-receiving elements with respect to the amount of incident light. It is therefore an important factor, in order to achieve a highly-sensitive solid-state imaging device, to accurately introduce the incident light into the light-receiving elements. For that reason, it is necessary to improve the light collection efficiency of an on-chip micro lens defined at the top of an image sensor. Currently existing on-chip micro lenses are resin spherical lenses and mounted on most solid-state imaging devices, such as CCDs and CMOS imaging sensors.

In recent years, a light-collecting element which has the periodic structure of a sub-wavelength region (Sub wavelength Lens: SWLL) has been attracting attention as a fine optical element which may replace micro lenses. Here, the “sub-wavelength region” represents a region which has a width (size) approximately equal to or smaller than that of a wavelength of subject light. A group of researchers of University of Delaware has proven the light-collecting efficiency of a lattice-shaped SWELL utilized instead of an aspheric Fresnel lens in simulations (see, for example, “D. W. Prather, Opt. Eng. 38 870-878 (1998)”). In this technique, a SWELL is formed by: dividing a conventional Fresnel lens (FIG. 1a) at a pitch of a zone region 9 (width: d), which is λ/2n, where λ is the wavelength of incident light and n is the refractive index of lens material; and performing linear approximation (FIG. 1b) and rectangular approximation (FIG. 1c) at each region. Similarly, it has also been reported that diffraction efficiency has been increased by controlling the line width of the periodic structure of a rectangular shape in a sub-wavelength region so as to form blazed-binary diffractive optical elements (see, for example, Japanese Patent Application Laid-Open Publication No. 2004-20957).

When a SWLL can be used as a light-collecting element for solid-state imaging devices, micro lenses can be formed by using general planer process techniques represented by optical lithography and electron lithography, and a shape of the lenses can be controlled without restriction.

The applicant has reported a solid-state imaging device with a SWLL mounted as an on-chip micro lens (see, for example, International Publication Pamphlet No. 05/059607).

FIG. 4A illustrates a basic structure of a solid-state imaging device 70 on which a light-collecting element 1 of SWLL is mounted. In FIG. 4A, it is illustrated that the SWLL which is structured so as to have fine submicron projections and recesses is mounted on a chip in place of a micro lens. Further, FIG. 4B is a top view of the above-described solid-state imaging device 70 arranged two-dimensionally. As illustrated in FIG. 4B, the light-collecting element 1 is shaped in a concentric structure and formed by high refractive-index material 10 [Tio₂ (n=2.53)] and low refractive-index material 11 [air (n=1.0)]. The light-collecting element 1 includes circular light-transmitting films, where a pitch (in other words, the width of the zone region 9) between adjacent circular light transmitting films is 0.2 μm. Further, the light-collecting element 1 has a film thickness of 0.5 μm.

The light-collecting element 1 which has the concentric structure is arranged so that the line width is the largest at the center area of the circle and becomes gradually smaller toward the outermost ring. In the case where the pitch is approximately equal to or smaller than that of the wavelength of incident light, the effective refractive index which has an effect on light is determined by the volume ratio between the high refractive-index material and the low refractive-index material. This structure includes a distributed index lens in which the effective refractive index becomes smaller from the center toward the edge of the concentric circle. In this case, a dividing pitch of the SWLL (the width of the zone region 9 of FIG. 1, for example) becomes approximately 0.1 μm to 0.3 μm in a visible light region, since the pitch depends heavily on the wavelength of a subject incident light.

However, in the conventional method described above, the marginal structure of the SWLL shares the same micro region 13 at the border of adjacent pixels (See FIG. 4B). As a result, the relationship between a cross section structure and the effective refractive index distribution of the SWLL becomes that as shown in FIG. 2. In the micro region 13 described above, a light-collecting ability of the SWLL decreases, since the effective refractive index does not fall completely.

FIG. 3 illustrates a light-collecting profile of the SWLL. The incident light travels upwards from underneath a sheet of paper and enters perpendicularly to the lens. Other than optic elements collected efficiently (collected light 35), optic elements traveling straight and irradiating a light-blocking layer (light-collecting loss 36) can be identified. This is attributed to the fact that the refractive index variation with light-collecting ability has not been achieved at the borders between pixels.

### SUMMARY OF THE INVENTION

The present invention has been conceived in view of the above-described problems, and aims to provide a solid-state imaging device including a light-collecting element capable of efficiently collecting incident light by improving reproducibility of refractive index distribution at the borders of pixels.

The present invention has improved reproducibility of refractive index distribution at the borders of pixels so as to provide a light-collecting element capable of efficiently collecting incident light. As described later in detail, a distributed index lens is provided, in which light-collecting ability at the edge of pixels has been improved by providing an air gap at the borders of pixels. With this, light-collecting loss and scattering are lowered, and light collection efficiency of the lens is improved.

In order to solve the above described problems, in the solid-state imaging device according to the present invention, plural unit pixels are arranged. Each of the unit pixels includes: a light-collecting element which has a predetermined effective refractive-index distribution; and an air gap between the light-collecting element and an adjacent light-collecting element located in another unit pixel. The air gap separates the effective refractive-index distribution and has a gap width approximately equal to a wavelength of incident light.

With this structure, the light-collecting loss is lowered, so that the light collection efficiency of the lens can be improved.

Further, the light-collecting element has an effective refractive-index distribution which is generated by a light-transmitting film that is partly formed. With this structure, the distributed index lens with a high-flexibility in design can be formed, so that the light-collecting element with high light-collection efficiency can be achieved.

Further, the air gap has a width of W_{gap} which satisfies λ/4<W_{gap}<4λ, where λ represents the wavelength of the incident light. With this structure, the light-collecting loss is lowered, so that the light collection efficiency of the lens can be improved.

Further, the air gap is arranged so as to extend to an upper surface of a color filter.

With this structure, the incident light is confined within each unit pixel, so that sensitivity of the sensor increases.

Further, the air gap is arranged so as to extend to an upper surface of a light-blocking layer.

This allows preventing divided incident light from leaking to adjacent pixels, so that color blending can be prevented.

Further, the air gap has a width which is in inverse proportion to a distance between the light-collecting element and a light-receiving element.

This allows efficiently confining light which has a wide incident angle within the unit pixel, so that sensitivity of the sensor can be increased.

Further, the air gap has a width which is in proportion to the wavelength of incident light entering into each of the unit pixels. This allows optimization of the lenses according to the color, so that color reproducibility increases.

Further, in the light-collecting element, a diagonal gap width of a region in which the element is formed is between λ/4 and λ, inclusive.

This allows including a wide opening, so that sensitivity of the sensor can be increased.

Further, the solid-state imaging device further includes, between the light-collecting element and another light-collecting element located in another unit pixel: either a light-transmitting film which forms the light-collecting element; or a light-transmitting film which has a lower refractive index nL than a refractive index of a planarization film. The light-transmitting film has a gap width W_{GAP} Ln which satisfies λ/4nL<W_{gap}Ln<4λ/nL. With this arrangement, the fine structure can be strengthened with light collection efficiency being maintained, so that reliability for impact protection and so on increase.

Further, in the solid-state imaging device, the air gap is formed in the light-collecting element in the case where the air gap is included in one of the unit pixels which is located at a center of a surface on which the plural unit pixels are formed, and the air gap is formed in a region between the light-collecting element and the light-blocking layer in the case where the air gap is included in another one of the unit pixels which is located at an edge of the surface.

With this structure, a solid-state imaging device without drops in sensitivity near the edge can be achieved in an optical module which has a wide incident angle against unit pixels near the edge.

Further, in the solid-state imaging device, the air gap is formed in a region between the light-collecting element and the light-blocking layer in the case where the air gap is included in one of the unit pixels which is located at a center of a surface on which the plural unit pixels are formed, and the air gap is formed in the light-collecting element in the case where the air gap is included in another one of the unit pixels which is located at an edge of the surface.

This allows increasing sensitivity of the sensor for the solid-state imaging device which includes unit pixels of large size.

Further, in the solid-state imaging device, the air gap of the unit pixel located at an edge of a surface has a gap width smaller than the gap width of the air gap of the unit pixel located at a center of the surface, on which the plural unit pixels are formed.

This allows oblique incident light to reach the light-receiving element efficiently, so that the solid-state imaging device which is superior in light-collecting characteristic for oblique incident light can be achieved.

Further, the manufacturing method according to the present invention is the manufacturing method for a solid-state imaging device in which plural unit pixels are arranged. Each of the unit pixels includes: a light-collecting element; a color filter which separates light collected by the light-collecting element according to color; a light-blocking layer which has an opening; a planarization film which is formed adjacent to the light-collecting element, the color filter or the light-blocking layer; a light-receiving element which converts light into an electric charge; and an air gap which has a width equal to or smaller than a wavelength of incident light, between the light-collecting element and an adjacent light-collecting element located in another unit pixel. The method includes forming the air gap through etching at the time of forming the light-collecting element. This allows forming air gap with ease, so that production cost can be reduced.

The solid-state imaging device according to the present invention includes light-collecting elements which have the air gap having a width approximately equal to or smaller than that of the wavelength of incident light. It is therefore possible to improve resolution and sensitivity, and to simplify manufacturing process.

### FURTHER INFORMATION ABOUT TECHNICAL BACKGROUND TO THIS APPLICATION

The disclosure of Japanese Patent Application No. 2007-024738 filed on Feb. 2, 2007 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1(a) to (c) illustrates cross section structures of a conventional sub-wavelength lens;

FIG. 2 illustrates a cross section structure and a refractive index distribution of a conventional sub-wavelength lens;

FIG. 3 illustrates propagation of light in a conventional sub-wavelength lens;

FIGS. 4A and 4B illustrate an example of the structure of a conventional solid-state imaging device (pixel) commonly used;

FIG. 5 illustrates a pixel array in accordance with the first embodiment;

FIG. 6 illustrates a cross section structure of a distributed index lens in accordance with the first embodiment;

FIGS. 7A to 7F illustrate basic structures of a distributed index lens in accordance with the first embodiment;

FIG. 8 illustrates a cross section structure of a pixel array in accordance with the first embodiment;

FIG. 9 illustrates a refractive index distribution of the lens in accordance with the first embodiment;

FIG. 10A illustrates propagation of light of the solid-state imaging device in accordance with the first embodiment;

FIG. 10B illustrates sensitivity of a sensor of the solid-state imaging device in accordance with the first embodiment;

FIGS. 11A to 11I illustrate a production process for a distributed index lens in accordance with the first embodiment;

FIG. 12 illustrates a cross section structure of a pixel in accordance with the second embodiment;

FIG. 13 illustrates propagation of light in a pixel in accordance with the second embodiment;

FIG. 14 illustrates a cross section structure of a pixel in accordance with the third embodiment;

FIG. 15 illustrates propagation of light in a pixel in accordance with the third embodiment;

FIGS. 16A and 16B illustrate a cross section structure of a pixel in accordance with the forth embodiment;

FIGS. 17A and 17B illustrate pixel arrays in accordance with the fifth embodiment;

FIGS. 18A and 18B illustrate pixel arrays in accordance with the sixth embodiment;

FIG. 19 illustrates a cross section structure of a pixel in accordance with the seventh embodiment;

FIG. 20 illustrates a pixel array and cross section structures of a pixel in accordance with the eighth embodiment;

FIG. 21 illustrates a pixel array and cross section structures of a pixel in accordance with the ninth embodiment;

FIG. 22 illustrates a pixel array and cross section structures of a pixel in accordance with the tenth embodiment; and

FIG. 23 illustrates a cross section structure of a pixel in accordance with the eleventh embodiment.

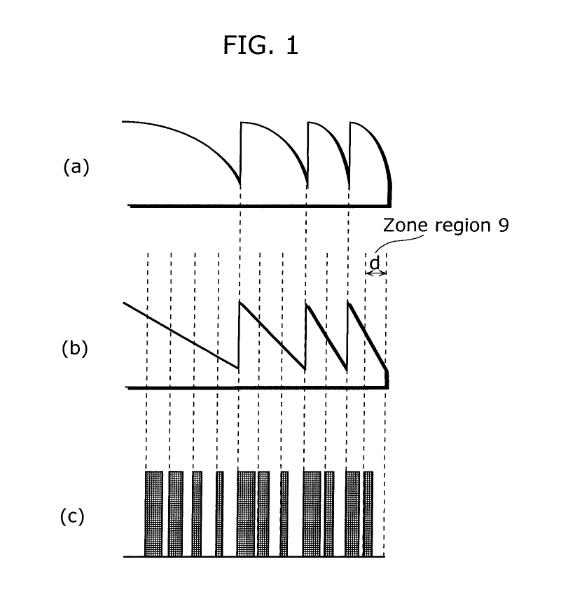

### DESCRIPTION OF THE PREFERRED EMBODIMENTS

Embodiments according to the present invention are described below with reference to the drawings. Note that, although the present invention is described with following embodiments and the drawings, they are intended merely for exemplification and not for the purpose of limitation.

### First Embodiment

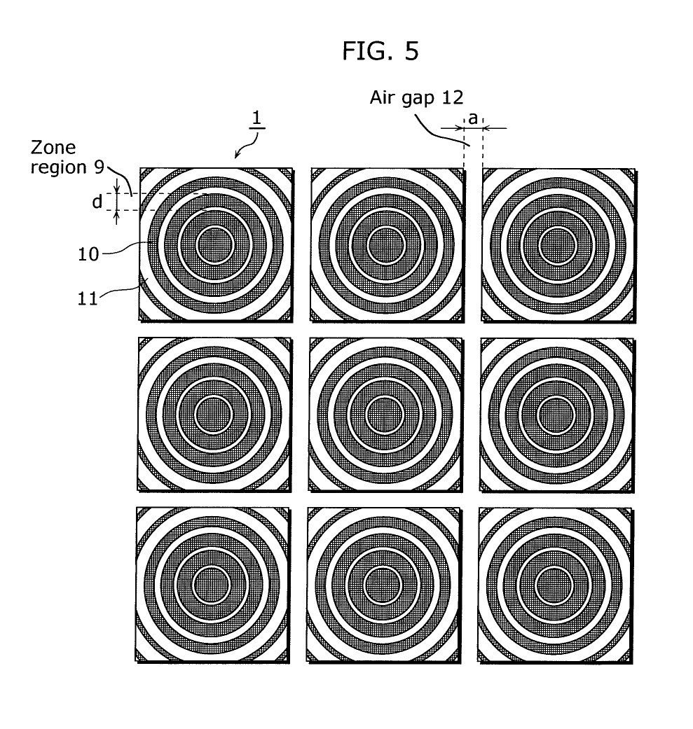

FIG. 5 illustrates a top view of a solid-state imaging device (more particularly, the top view of a light-collecting element) in accordance with the present embodiment. The light-collecting element of FIG. 5 has a structure in which SiO₂ (n=1.43) is curved out to define a concentric pattern and the surrounding medium is air (n=1). In the present embodiment, SiO₂ is “dense” at the center of a pixel, and becomes “sparse” toward outer rings. In the case where a micro region (a zone region) 9, in which high refractive-index material 10 (SiO₂, in this embodiment) and low refractive-index material 11 (air, in this embodiment) coexist, has a width (d) approximately equal to or smaller than a wavelength of incident light (λ), an effective refractive index which has an effect on light is determined by the volume ratio between the two types of materials in the zone region. More specifically, the effective refractive-index increases by increasing high refractive-index material in the zone region, and decreases conversely by reducing high refractive-index material. The light-collecting element 1 as shown in FIG. 5 is a distributed index lens in which an optical center consists with the center of a pixel. Further, an air gap 12 is provided between two adjacent light-collecting elements.

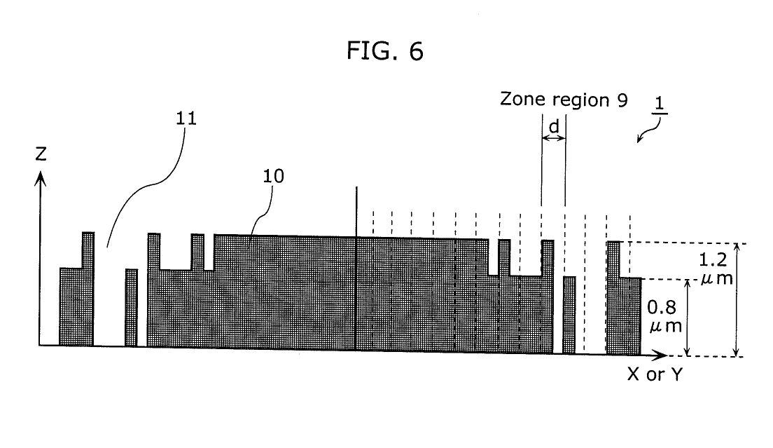

FIG. 6 illustrates a cross section of the light-collecting element in accordance with the present embodiment. The light-collecting element 1 has a concentric structure (also referred to as “two-tiered concentric structure”) in which the film thickness includes 1.2 μm and 0.8 μm.

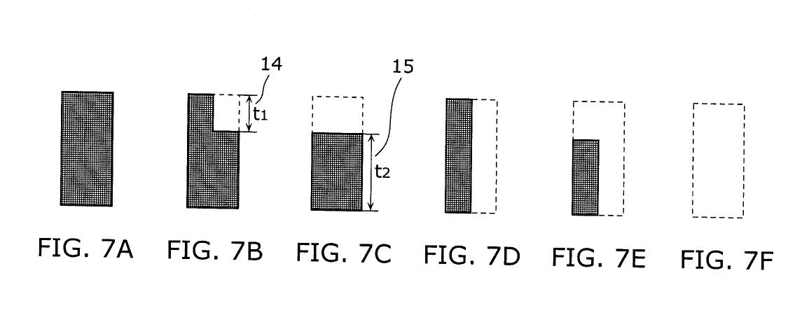

FIGS. 7 A to 7F illustrates six basic structures of the light-collecting element having the two-tiered concentric structure in accordance with the present embodiment. FIG. 7A illustrates the densest structure, in other words, the structure in which the effective refractive index is the highest. The effective refractive index becomes lower as the structure changes from FIG. 7B toward FIG. 7F. Here, a film thickness 14 of the upper tier (a light incoming side) and a film thickness 15 of the lower tier (a substrate side) are 0.4 nm and 0.8 nm, respectively, and a film-thickness ratio (the upper tier/the lower tier) is “0.5”.

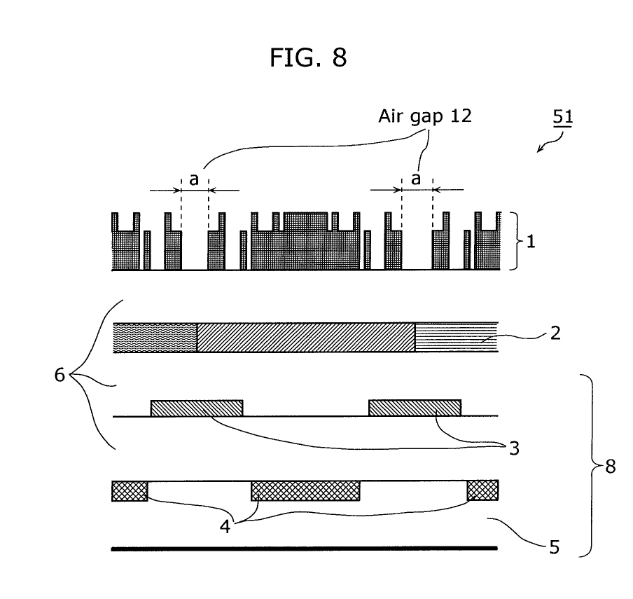

Next, the basic structure of the solid-state imaging device in accordance with the present embodiment is described. FIG. 8 is the cross section of the solid-state imaging device 51 (also referred to as “unit pixel”) in accordance with the present embodiment. The solid-state imaging device 51 has a square size of 5.6 μm and includes: the light-collecting element 1; a color filter 2; a light-blocking layer (also referred to as a “light-blocking film”) 3; a light-receiving element (Si photo diode) 4; and a Si substrate 5. Note that the light-blocking layer 3, the light-receiving element 4 and the Si substrate 5 are included in a semiconductor integrated circuit 8. As described above, the air gap 12 is provided between two adjacent light-collecting elements.

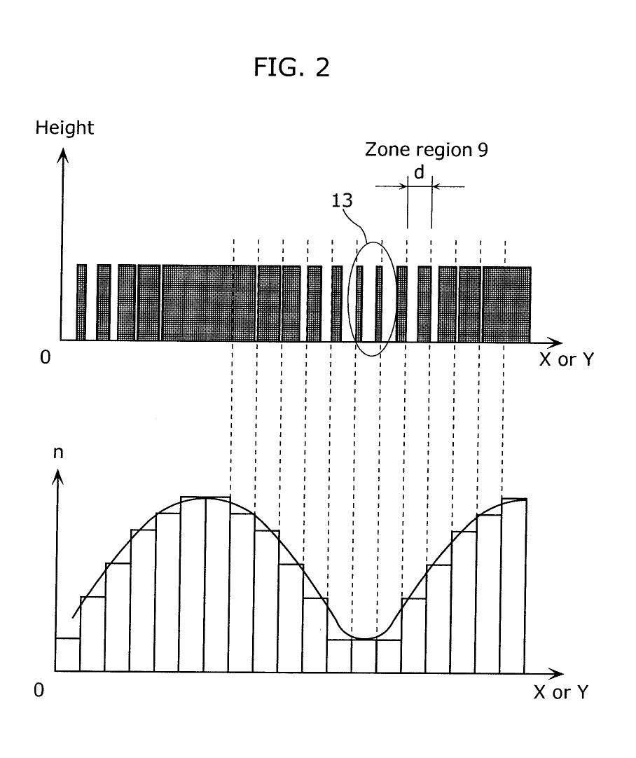

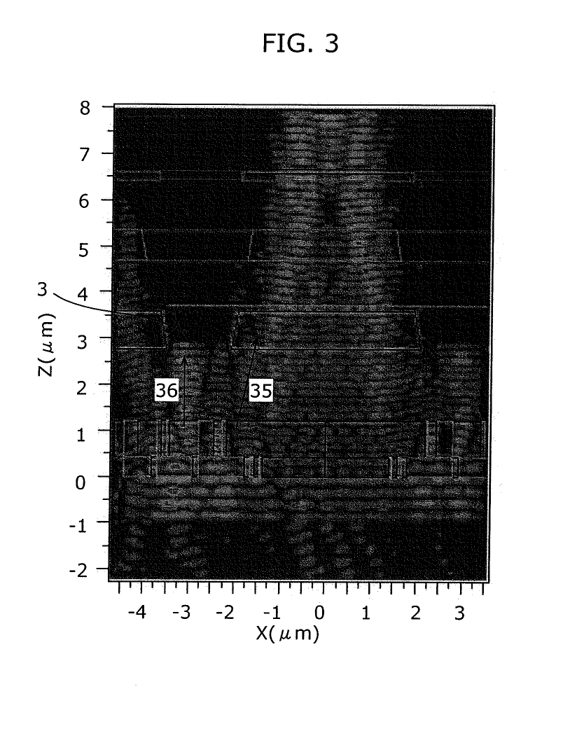

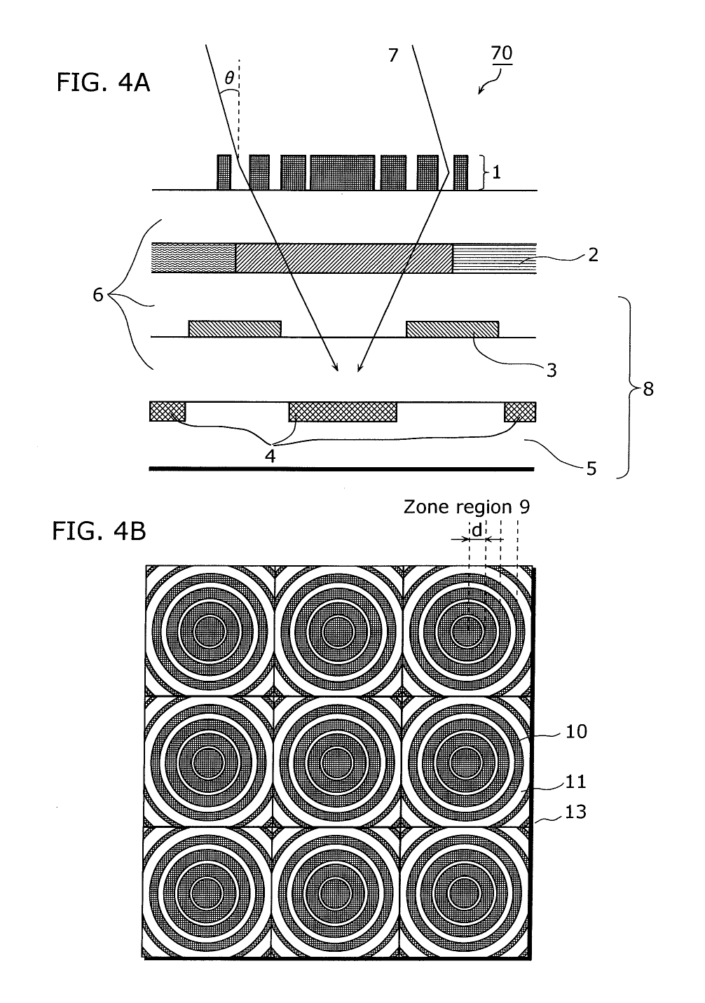

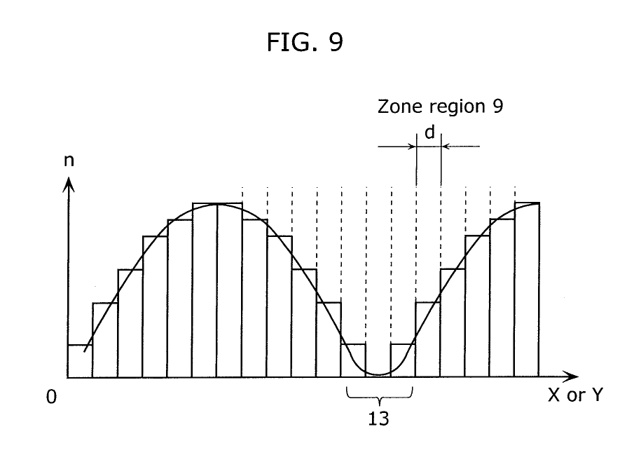

FIG. 9 illustrates an effective refractive index distribution of the light-collecting element 1 of the present invention. Contrary to the conventional example as shown in FIG. 2 in which the distribution is not separated, it can be seen that, in the light-collecting element of the present invention, the refractive index becomes zero at a certain point, in other words, the refractive index distribution is separated. Here, in the case where the wavelength of incident light is A, a gap width W_{GAP} 12 of the air gap 12 satisfies the following expression.

λ/4<W_{GAP}<4λ (1)

Since the effective refractive index of the structure at the border between pixels has an effect on incident light in the case where W_{GAP} does not satisfy the expression described above, the refractive index can not be separated.

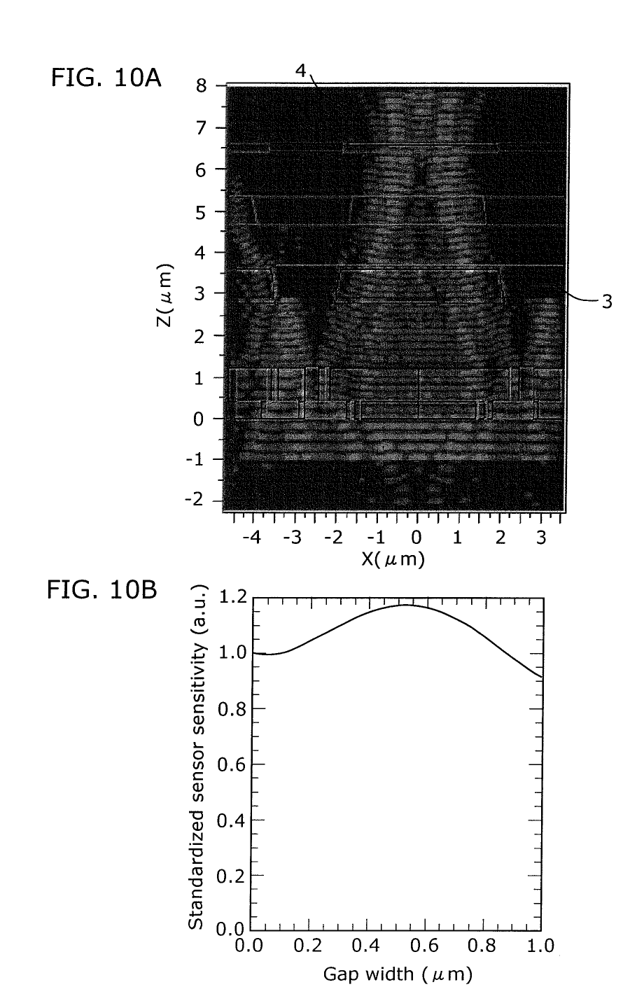

FIG. 10A illustrates a light-collecting profile of the light-collecting element 1 in accordance with the present embodiment. It can be seen, from FIG. 10A, that incident light entering perpendicular to the lens is efficiently collected without interruption by the light-blocking layer. This also indicates that the refractive index distribution with high light-collecting ability has been achieved at the borders between pixels. FIG. 10B indicates a relationship between the sensitivity of the sensor and the gap width in the case where the incident light is a green light (λ=0.55 μm). It is standardized here that the sensitivity of the sensor is 1 when the gap width is 0 μm. As is clear from FIG. 10B, the sensitivity is enhanced as the gap width increases and reaches the maximum when the gap width is approximately 0.5 μm. This satisfies the condition of the expression (1) described above.

Note that, although it has been described in this embodiment for easier understanding that the light-collecting element 1 is structured based on the basic structures as illustrated in FIG. 7, other structures also can be employed. For example, a convex structure can be formed by combining FIG. 7B and FIG. 7C, and a concave structure can be formed by combining FIG. 7B and FIG. 7D. At this time, in the case where such basic structures are employed in the area with approximately half-width of the wavelength of the incident light, the same light-collecting characteristic can be obtained.

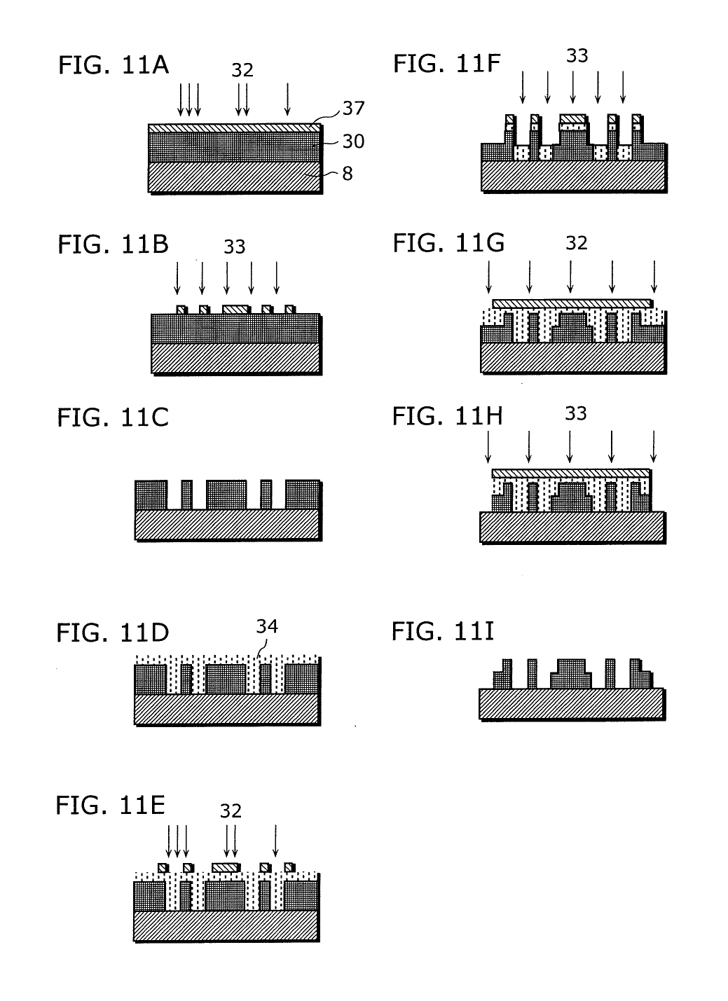

FIGS. 11A to 11I illustrates a manufacturing process for the light-collecting element 1 in accordance with the present embodiment. Here, the light-collecting element 1 has the two-tiered structure and is formed through three times of photolithography and etching.

First, the semiconductor integrated circuit 8 including the light-receiving element, the light-blocking layer, and the color filter is formed on the Si substrate through a regular process for forming semiconductor integrated circuits (details thereof are not illustrated in FIGS. 11A to 11I described above). The size of a single unit pixel is 5.6 μm square and the size of a light-receiving unit is 3.5 μm. After that, a SiO₂ film 30 is formed using a Chemical Vapor Deposition (CVD) device and a resist 37 is applied thereon (FIG. 11A).

Patterning is performed subsequently through photolithography 32 (FIG. 11A). The SiO₂ film 30 and the resist 37 have a thickness of 1.2 μm and 0.5 μm, respectively. After the development, etching 33 is performed (FIG. 11B) to form a fine structure on the surface of pixels (FIG. 11C). After removal of the resist 37, Bottom Anti-Reflective Coating (BARK) material 34 is applied for planarization (FIG. 11D).

Following the application of the resist 37, patterning is again performed through photolithography 32 (FIG. 11E). After the etching is performed (FIG. 11F), the resist 37 and the BARK material are removed. Similar process is subsequently performed (FIGS. 11F and 11G) to form the air gaps 12 between unit pixels (FIG. 11I).

In the manufacturing process for the light-collecting element 1 in accordance with the present embodiment, a phase mask is used in the photolithography processing for forming a fine structure of which the line width of the concentric circle is approximately 0.1 μm. In the phase mask, phase shifters which cause phase differences of 0 and n in incident light need to be arranged alternately. Accordingly, it is very difficult to design a pattern, such as the air gap 12, which extends across the entire unit pixels.

However, the manufacturing process according to the present embodiment allows the air gap 12 to be formed after forming the fine structure. Consequently, more flexibility is allowed for designing, thereby lowering the production cost.

Further, although the light-collecting element 1 is formed to have two tiers in the present embodiment, lenses may be formed to have further tiers through the process in which the photolithography and the etching illustrated in FIG. 11a to 11I are combined. As the number of tiers increases, the number of a gradation sequence increases, thereby further improving the light collection efficiency.

In the following embodiments, the above-described process is applied for formation of the lens.

### Second Embodiment

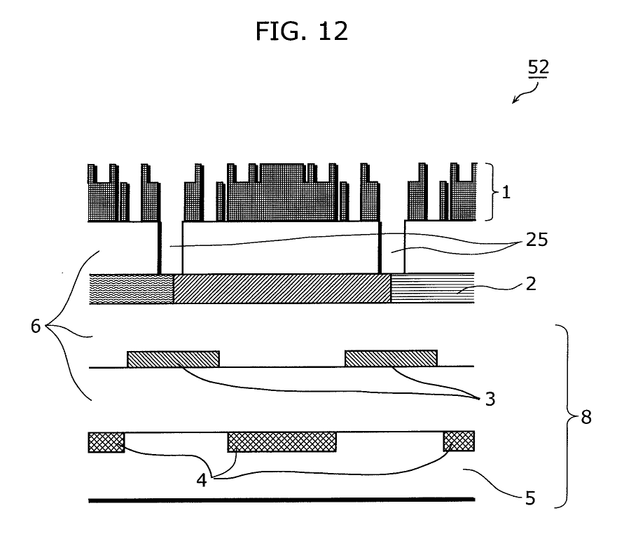

FIG. 12 illustrates a cross section of an unit pixel in a solid-state imaging device 52 of the VGA specification (310 thousand pixels) in accordance with the second embodiment. FIG. 12 illustrates air gaps 25 arranged so as to extend to the upper surface of a color filter 2. In the present embodiment, since SiO₂ (n=1.43) is used for the planarization film 6 on the color filter 2, light with incident angle of not more than 44 degrees is fully reflected. In this case, most light collected by the light-collecting element 1 is confined within the each unit pixel and the amount of light escaping to adjacent unit pixels is reduced.

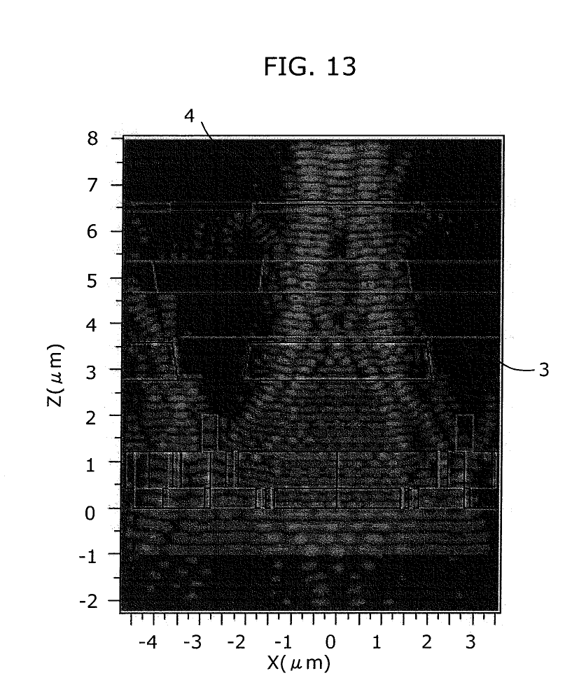

FIG. 13 illustrates a profile of propagation of light according to the present embodiment. It can be seen from FIG. 13 that incident light is collected efficiently. This allows the amount of light entering the color filter 2 to be increased, thereby improving the sensitivity and the color reproducibility.

### Third Embodiment

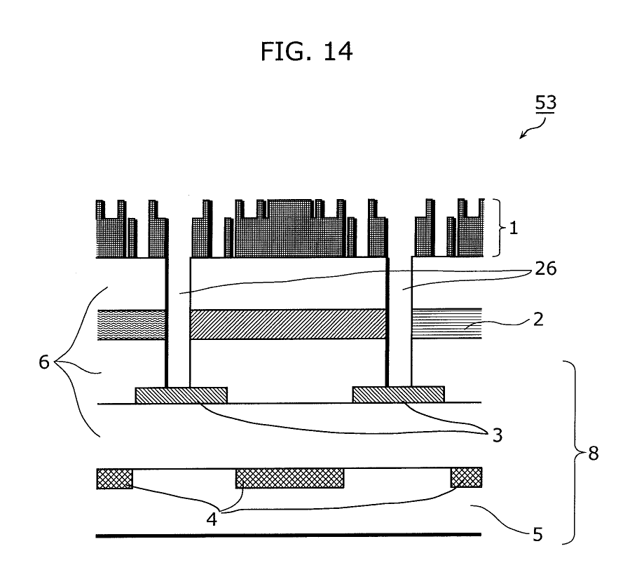

FIG. 14 illustrates a cross section of a unit pixel in a solid-state imaging device 53 of the VGA specification (310 thousand pixels) in accordance with third embodiment. FIG. 14 illustrates air gaps 26 arranged so as to extend to the upper surface of a light-blocking layer 3. In this embodiment, a color filter 2 is divided by the air gaps 26, so that color-separated incident light is confined within the unit pixel.

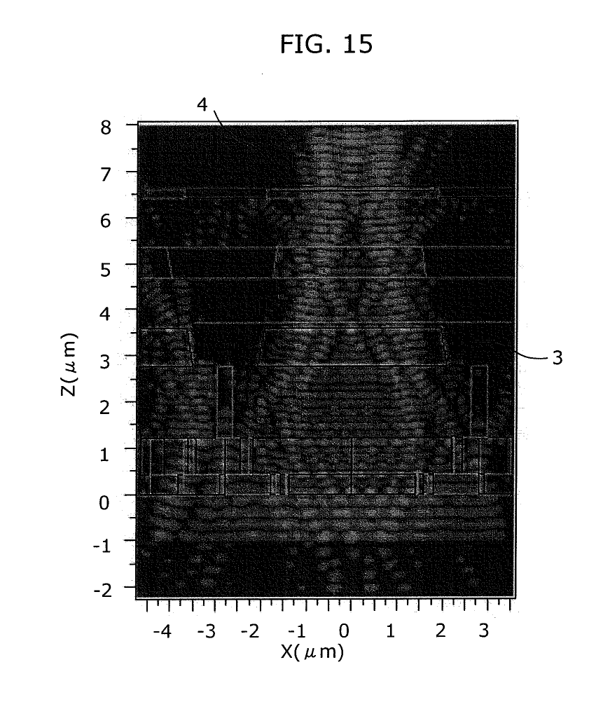

FIG. 15 illustrates a profile of propagation of light in accordance with the present embodiment. It can be seen from FIG. 15 that incident light is confined within the unit pixel and collected efficiently by a light-receiving element 4. With this, it is possible to prevent the collected light from escaping to adjacent unit pixels and to reduce the color blending. Accordingly, the color reproducibility can be improved.

### Forth Embodiment

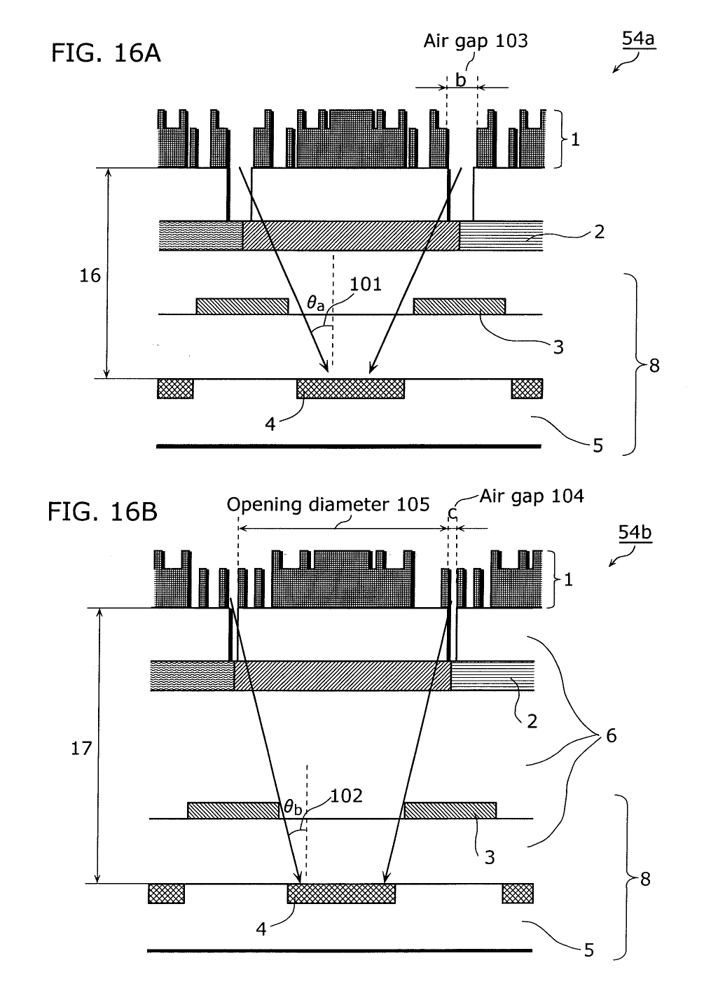

FIGS. 16A and 16B illustrate cross sections of unit pixels in solid-state imaging device 54a and 54b of VGA specification (310 thousand pixels) in accordance with the forth embodiment. It can be seen from FIGS. 16A and 16B that the solid-state imaging devices 54a and 54b include the air gap 103 with a gap width b and the air gap 104 with a gap width c, respectively. The gap widths b and c are not equal when the distance between a light-collecting element 1 and a light-receiving element 4 (hereinafter referred to as “the distance between LE and PD”) differs between the solid-state imaging devices 54a and 54b. The unit pixel in which the distance between LE and PD is short is formed so as to include the air gap having a wide width (also referred to as a “gap width”). Conversely, the unit pixel in which the distance between LE and PD is long is formed so as to include the air gap having a small gap width. Since a converging angle 101 becomes large in the unit pixels in which the distance 16 between LE and PD is short, a large width b is provided in the air gap 103 so as to strengthen the confinement of oblique light. Consequently, light collection efficiency is raised and sensitivity of the solid-state imaging device improves.

On the other hand, since the converging angle 102 becomes small in the unit pixels in which the distance 17 between LE and PD is long, a small width c is provided in the air gap 104 and an opening diameter 105 is set large with respect to the light entering the light-collecting element 1. This enables increase of the amount of incident light, so that sensitivity can be improved.

### Fifth Embodiment

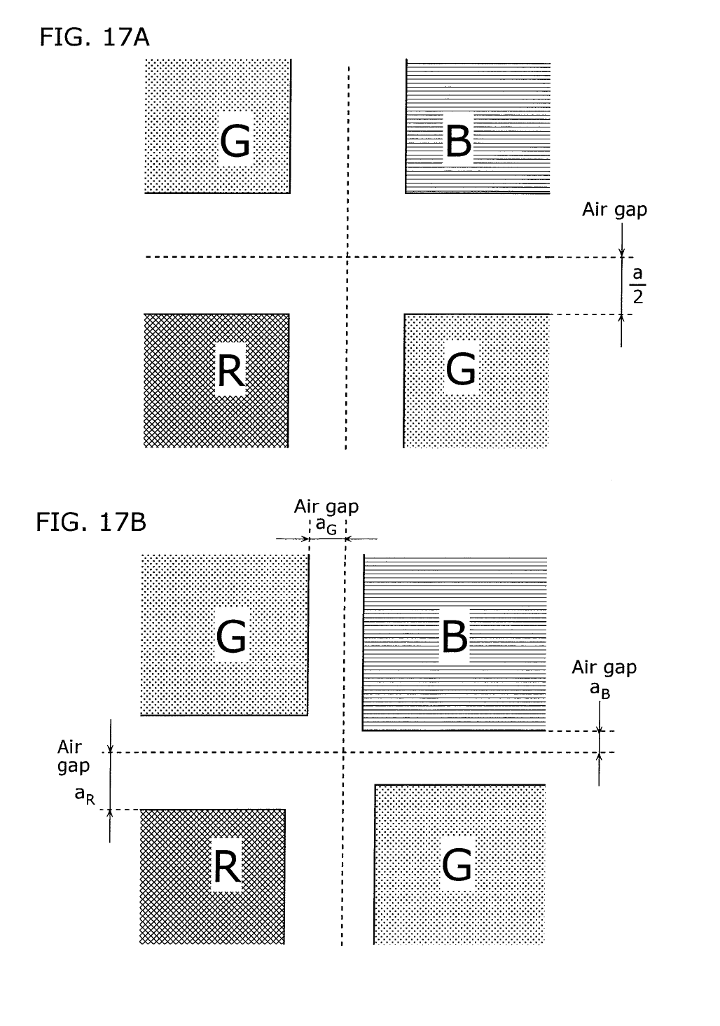

FIGS. 17A and 17B illustrate arrangements of unit pixels in a solid-state imaging device 55 of the VGA specification (310 thousand pixels) in accordance with the fifth embodiment. As illustrated in FIG. 17B, the width of air gap is varied in accordance with the wavelength of incident light corresponding to each unit pixel. It is obtained from the above expression (1) that the gap width of unit pixels for R light, G light and B light is 150 nm, 130 nm and 115 nm, respectively.

This allows the gap width to be minimized, so that an opening ratio increases. Accordingly, the sensitivity of the solid-state imaging device improves.

On the other hand, by equalizing the gap width (a/2, in FIG. 17A) of the air gap as illustrated in FIG. 17A, the opening ratio between pixels becomes the same. Accordingly, it is possible to simplify processes (the photolithography processing, for example) and lower the production cost.

### Sixth Embodiment

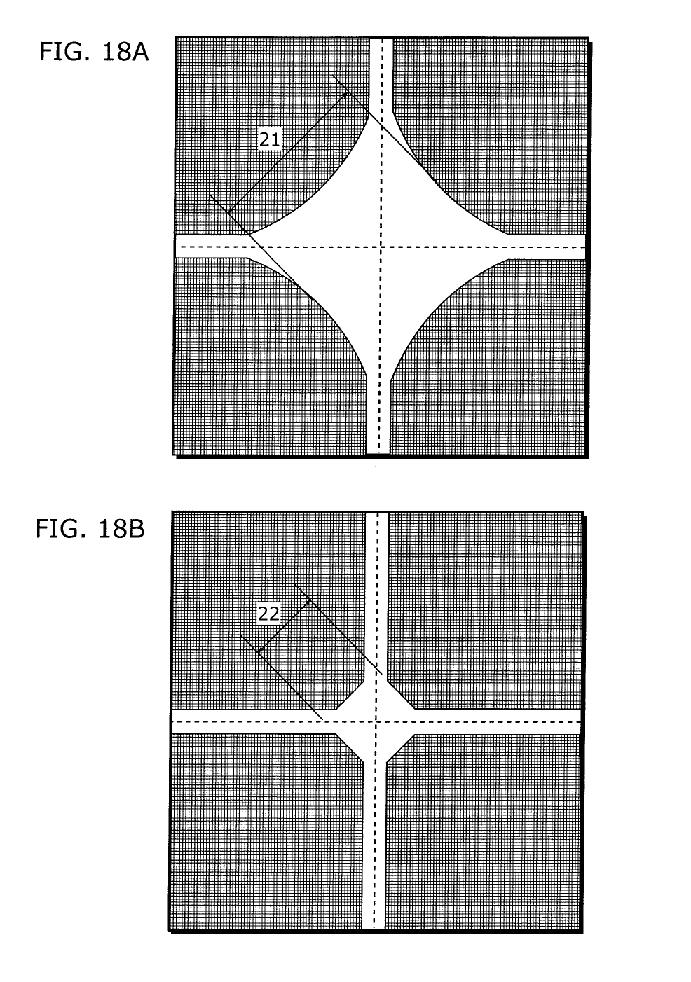

FIGS. 18A and 18B illustrate arrangements of unit pixels in a solid-state imaging device of the VGA specification (310 thousand pixels) in accordance with the sixth embodiment. FIG. 18A illustrates the arrangement of unit pixels in the solid-state imaging device on which a conventional on-chip micro lens is mounted. There always exists a diagonal gap 21 between unit pixels, since the on-chip micro lens is formed through heat reflow. The diagonal gap 21 is approximately several hundred nm. Accordingly, incident light entering this region is not collected, which results in lowered sensitivity.

On the other hand, a light-collecting element in accordance with the present embodiment is arranged so as to have a diagonal gap 22 between λ/4 and λ, inclusive (FIG. 18B). With this, it is possible to obtain light collection efficiency of approximately 1 at a pixel-angle and to improve the sensitivity.

### Seventh Embodiment

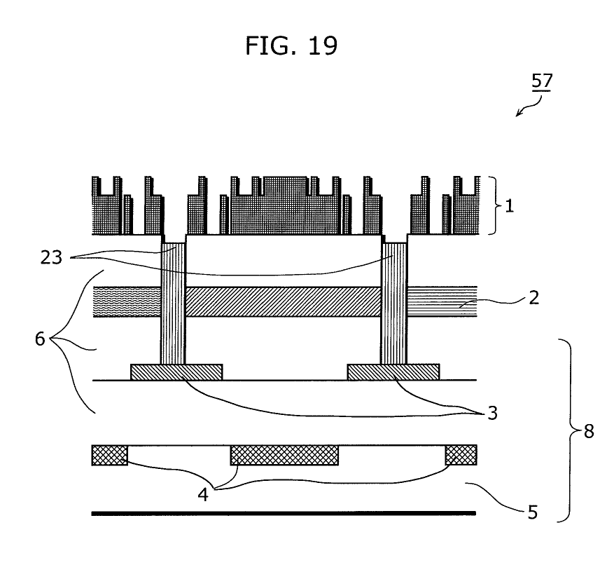

FIG. 19 illustrates a cross section of an unit pixel in a solid-state imaging device of the VGA specification (310 thousand pixels) in accordance with the seventh embodiment. In the present invention, the air gaps are filled with CYTOP™ (n=1.34) 23 which has a lower refractive index than that of TEOS™ (n=1.45) which makes up a light-collecting element and a planarization film. Although the difference in the refractive index is approximately “0.11”, the entire reflection angle becomes 67.5°. Accordingly, light entering the sensor surface at an angle of 22.5° is confined within the pixel. When a refractive index ratio between the filling material and the planarization film is Rn (=the refractive index of the filling material/the refractive index of the planarization film) and a corresponding incident angle is θ(°), the relation is represented as the following expression.

θ=90−sin(Rn) (2)

In this case, the gap width W_{GAP}LN12 satisfies the following expression.

λ/4nL<W_{GAP}LN<4λ/nL (3)

Here, nL represents the refractive index of the filling material, “1.34” in the present embodiment. By satisfying the above expression (3), the refractive index distribution of the light-collecting element is separated at each unit pixel (FIG. 19), and the light collection efficiency at surrounding section of unit pixel is not lowered. Further, this “filling” allows the convex structure to be disappeared, thereby increasing the strength and improving reliability for resistance to impact and vibration.

### Eighth Embodiment

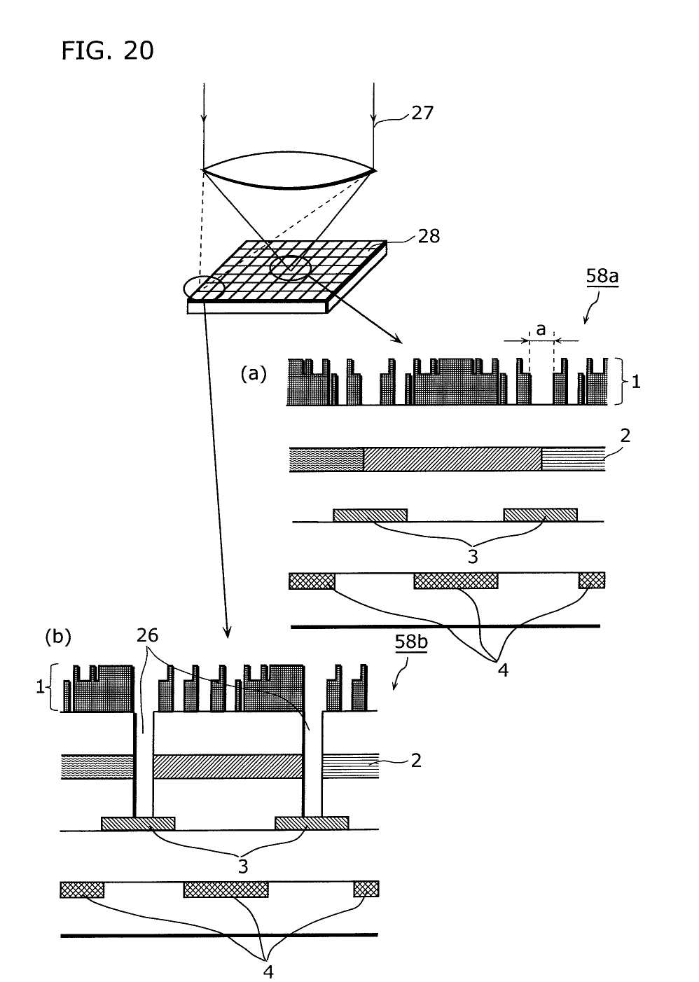

FIG. 20 illustrates: an optical module used for mobile phone cameras on which a solid-state imaging device having three million pixels is mounted; and a cross section of a unit pixel in accordance with the eighth embodiment. The unit pixel of the present embodiment has a square size of 2.2 μm. In the optical module in a short focus system, such as mobile phone cameras, although light enters a unit pixel 58a perpendicularly near the center, light enters a unit pixel 58b near the edge at an angle of at least 30 degrees.

In the present embodiment, therefore, an air gap is provided only in the light-collecting element 1 in the unit pixel 58a near the center, and the air gap is arranged so as to extend to the upper surface of a light-blocking layer 3 in the unit pixel 58b near the edge. This allows a wide opening in the unit pixel near the center, so that sensitivity of the sensor can be improved. Further, incident light is confined within each unit pixel near the edge, so that sensitivity of the sensor can be improved. The structure of the unit pixel of the present embodiment is especially effective for the solid-state imaging device which has the pixel size of equal to or less than 3 μm.

### Ninth Embodiment

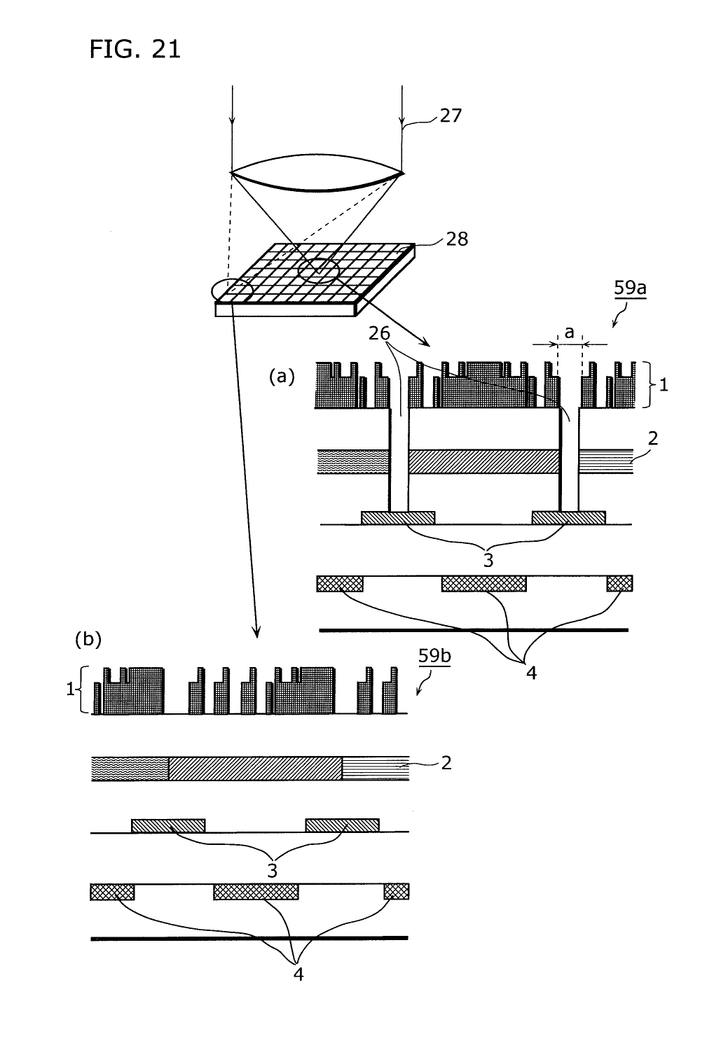

FIG. 21 illustrates: an optical module used for a vehicle-mounted camera on which a solid-state imaging device of the VGA specification (310 thousand pixels) is mounted; and a cross section of a unit pixel according to the ninth embodiment. The unit pixel of the present embodiment has a square size of 5.6 μm. When the unit pixels is approximately this size, it is possible to control the shape of an on-chip micro lens. Accordingly, high-sensitivity is obtained for the unit pixel near the center. On the other hand, the light-collecting element of the present embodiment has a structure of fine projections and recesses, so that light-scattering occurs at the surface. Accordingly, there is a possibility that the light collection efficiency may decrease.

In the present embodiment, therefore, an air gap is arranged so as to extend to the upper surface of a light-blocking layer 3 in order to improve the sensitivity of the unit pixel 59a near the center. Light transmitted through the light-collecting element 1 is guided into the light-receiving element 4 without scattering and reflecting on other unit pixels, so that the sensitivity of the sensor increases. Note that, in the solid-state imaging device which includes a large unit-pixel size as in the present embodiment, since the air gap takes up only a small area in the pixel region (approximately seven percent), the opening ratio changes only slightly and reduction in the amount of incident light is very little.

Consequently, the solid-state imaging device of the present embodiment has the sensitivity which is in the level of equal to or more than that of the currently existing solid-state imaging devices. Further, since the incident angle of light is small (approximately 15 degrees) in the unit pixel 59b located near the edge, the air gap is formed only in the light-collecting element. By minimizing processing toward the depth direction, it is possible to improve the strength of a product against impact and vibration.

### Tenth Embodiment

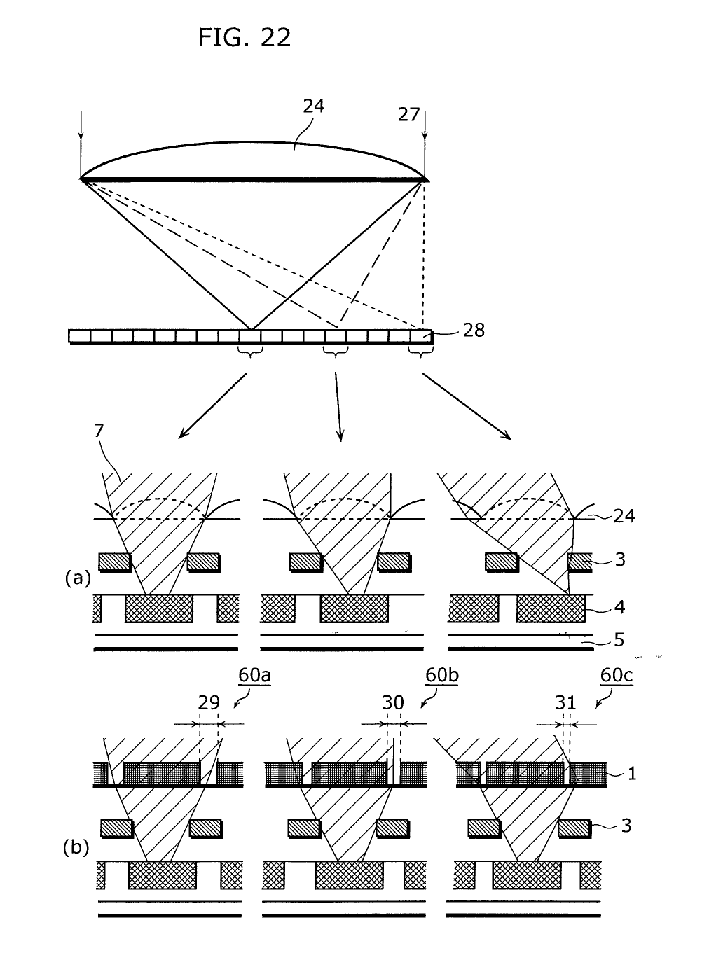

FIGS. 22(a) and (b) illustrates: an optical module used for a mobile phone camera on which a solid-state imaging device having three million pixels is mounted; and a cross section of a unit pixel, in accordance with the tenth embodiment. FIG. 22(a) illustrates a cross section of the solid-state imaging device having a shrink structure and includes an on-chip micro lens 24 thereon.

As described above, although light enters a unit pixel perpendicularly near the center, light enters a unit pixel at a high angle near the edge. This is an especially noted problem in optical modules of short focus system, such as mobile phone cameras. In currently existing solid-state imaging devices, the position of a light-blocking layer and an on-chip micro lens are shifted (shrunk) toward the center of the solid-state imaging device compared to the center of the light-receiving element so as to improve peripheral sensitivity. However, as the size of a unit pixel becomes finer, the difficulty in forming the shrunk light-blocking layer and the micro lens has been increasing.

In this embodiment, the light-collecting element having a refractive index distribution of the Fresnel type is formed so as to be decentered with respect to the center of a pixel, so that the same effect with shrinking is successfully obtained (see, for example, International Publication Pamphlet No. 05/059607). In this case, since the light-collecting element has a larger amount of decentering shift in a unit pixel near the edge, a Fresnel zone of a higher-order appears.

In this embodiment, therefore, the line width of the air gap in a unit pixel near the edge is arranged to be thin so as to prevent the structure of a higher mode zone from disappearing. with this, it is possible to obtain clear images without decreasing peripheral sensitivity. Further, the pixel unit near the center includes a light-transmitting film formed flat (see, for example, FIG. 6), so that a large air gap is ensured and the separation of the refractive index distribution is strengthened. As a result, it is possible to increase the light collection efficiency and the sensitivity of the sensor.

### Eleventh Embodiment

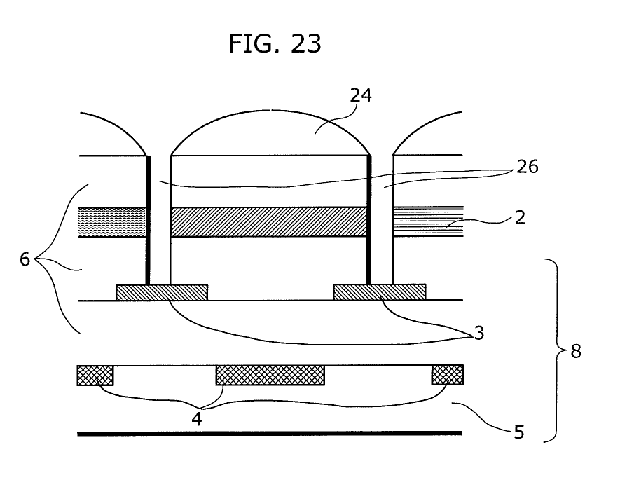

FIG. 23 illustrates a cross section of a unit pixel in a solid-state imaging device of the VGA specification (310 thousand pixels) in accordance with the eleventh embodiment. Although the distributed index lens is utilized as the light-collecting element in the aforementioned embodiment, on-chip micro lenses 24 may be mounted as illustrated in FIG. 23. The micro lenses 24 can be formed with a great controllability especially in the case where the solid-state imaging device has unit pixels of the large size, so that a high-sensitive sensor can be achieved.

Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

### INDUSTRIAL APPLICABILITY

A solid-state imaging device of the present invention can be used for products related to image sensors, such as a digital video camera, a digital still camera, a camera-equipped cell phone, a surveillance camera, a vehicle-mounted camera, and a broadcast camera. The solid-state imaging device of the present invention is useful industrially, since it is possible to improve the performance and to lower the price of the device compared to conventional solid-state imaging devices.

What is claimed is:

1. A solid-state imaging device in which a plurality of unit pixels are arranged,
wherein each of said unit pixels includes:
a light-collecting element which has a predetermined effective refractive-index distribution; and
an air gap between said light-collecting element and an adjacent light-collecting element located in another unit pixel, which separates the effective refractive-index distribution, and
said air gap has a gap width approximately equal to a wavelength of incident light.

2. The solid-state imaging device according to claim 1,
wherein said light-collecting element has an effective refractive-index distribution which is generated by a light-transmitting film that is partly formed.

3. The solid-state imaging device according to claim 1,
wherein said air gap has a width of W_{gap} which satisfies
λ/4<W_{gap}<4λ, where λ represents the wavelength of the incident light.

4. The solid-state imaging device according to claim 1,
wherein said air gap is arranged so as to extend to an upper surface of a color filter.

5. The solid-state imaging device according to claim 1,
wherein said air gap is arranged so as to extend to an upper surface of a light-blocking layer.

6. The solid-state imaging device according to claim 1,
wherein said air gap has a width which is in inverse proportion to a distance between said light-collecting element and a light-receiving element.

7. The solid-state imaging device according to claim 1,
wherein said air gap has a width which is in proportion to the wavelength of incident light entering into each of said unit pixels.

8. The solid-state imaging device according to claim 1,
wherein, in said light-collecting element, a diagonal gap width of a region in which said element is formed is between λ/4 and λ, inclusive.

9. The solid-state imaging device according to claim 1, said device further comprising, between said light-collecting element and said another light-collecting element located in said another unit pixel: either a light-transmitting film which forms said light-collecting element; or a light-transmitting film which has a lower refractive index nL than a refractive index of a planarization film,
wherein said light-transmitting film has a gap width W_{GAP} Ln which satisfies
λ/4nL<W_{gap} Ln<4λ/nL.

10. The solid-state imaging device according to claim 1,
wherein said air gap is formed in said light-collecting element in the case where said air gap is included in one of said unit pixels which is located at a center of a surface on which said plurality of unit pixels are formed, and
said air gap is formed in a region between said light-collecting element and said light-blocking layer in the case where said air gap is included in another one of said unit pixels which is located at an edge of the surface.

11. The solid-state imaging device according to claim 1,
wherein said air gap is formed in a region between said light-collecting element and said light-blocking layer in the case where said air gap is included in one of said unit pixels which is located at a center of a surface on which said plurality of unit pixels are formed, and
said air gap is formed in said light-collecting element in the case where said air gap is included in another one of said unit pixels which is located at an edge of the surface.

12. The solid-state imaging device according to claim 1,
wherein said air gap of said unit pixel located at an edge of a surface has a gap width smaller than the gap width of said air gap of said unit pixel located at a center of the surface, said plurality of unit pixels being formed on the surface.

13. A manufacturing method for a solid-state imaging device in which a plurality of unit pixels are arranged,
wherein, each of said unit pixels includes: a light-collecting element; a color filter which separates light according to color, the light collected by said light-collecting element; a light-blocking layer which has an opening; a planarization film which is formed adjacent to the light-collecting element, the color filter or the light-blocking layer; a light-receiving element which converts light into an electric charge; and an air gap which has a width equal to or smaller than a wavelength of incident light, between the light-collecting element and an adjacent light-collecting element located in another unit pixel,
said method comprising forming the air gap through etching at the time of forming the light-collecting element.
